(19) United States
(12) Patent Application Publication
(10) Pub. No.: US 2012/0138129 A1
(43) Pub. Date: Jun. 7, 2012

(54) BIFACIAL SOLAR CELL

(75) Inventors: Kyung Hyun KIM, Daejeon (KR); Dae-Hyung CHO, Seoul (KR)

(73) Assignee: ELECTRONICS AND TELECOMMUNICATIONS RESERACH INSTITUTE, Daejeon (KR)

(21) Appl. No.: 13/205,664

(22) Filed: Aug. 9, 2011

(30) Foreign Application Priority Data
Dec. 7, 2010 (KR) 10-2010-0124444

(51) Int. Cl. H01L 31/06

(52) U.S. Cl. 136/255

(57) ABSTRACT

Provided is a bifacial solar cell. The bifacial solar cell includes: a transparent substrate having a first side and a second side facing each other; a first transparent electrode disposed on the first side of the transparent substrate; a first light absorbing layer disposed on the first transparent electrode and exposing the first transparent electrode at one edge; a second transparent electrode disposed on the first light absorbing layer; a first metal electrode pad disposed on the exposed first transparent electrode; a third transparent electrode disposed below the second side of the transparent substrate; a second light absorbing layer disposed below the third transparent electrode and exposing the third transparent electrode in correspondence to the exposed first transparent electrode; a fourth transparent electrode disposed below the second light absorbing layer; and a second metal electrode pad disposed below the exposed third transparent electrode.

### CROSS-REFERENCE TO RELATED APPLICATIONS

This U.S. non-provisional patent application claims priority under 35 U.S.C. §119 of Korean Patent Application No. 10-2010-0124444, filed on Dec. 7, 2010, the entire contents of which are hereby incorporated by reference.

### BACKGROUND OF THE INVENTION

The present invention disclosed herein relates to a solar cell, and more particularly, to a bifacial solar cell.

A compound thin film solar cell consists of a glass substrate, metal electrodes stacked sequentially on the glass substrate, a light absorbing layer of CdTe, CuInSe, and CuIn(Ga)Se, a buffer layer of CdS or ZnS, a transparent electrode, an anti-reflection layer of MgF₂, and a grid electrode. The compound thin film solar cell having the above structure may have an opaque property due to the metal electrode (i.e., a rear electrode). The opaque compound thin film solar cell has no limitation in transmitting solar light into the light absorbing layer and also, the metal electrode as the rear electrode serves to connect generated electric charges to a conducting wire.

A compound thin film solar cell doesn't need to have a transparent structure when it is manufactured for a solar power system or a typical panel installed at the roof of a building. However, the opaque compound thin film solar cell cannot be used for a window or a glass outer wall of a building, which needs to transmit external solar light into the inside and also, the building's aesthetics are compromised with a partially open type.

Moreover, an amorphous silicon solar cell possible for a transparent solar cell is used for an open type or a transparent type solar cell but when it is used for a partially open type, an aesthetic view is low and also, if it is used for a transparent type, low efficiency of an about 4.5% level is provided when a standard transmittance reaches about 10%. Additionally, a dye-sensitized solar cell has been greatly studied until now as a transparent solar cell and has cell efficiency of an about 10% level currently. However, its durability is 5 years and thus its usability is low. Due to these limitations, it is difficult for a typical solar cell structure and material to be used as a building material of a Building Integrated Photo-Voltaic (BIPV).

### SUMMARY OF THE INVENTION

The present invention provides a bifacial solar cell with improved efficiency and durability appropriate for a building material of a Building Integrated Photo-Voltaic (BIPV).

Embodiments of the present invention provide bifacial solar cells including: a transparent substrate having a first side and a second side facing each other; a first transparent electrode disposed on the first side of the transparent substrate; a first light absorbing layer disposed on the first transparent electrode and exposing the first transparent electrode at one edge; a second transparent electrode disposed on the first light absorbing layer; a first metal electrode pad disposed on the exposed first transparent electrode; a third transparent electrode disposed below the second side of the transparent substrate; a second light absorbing layer disposed below the third transparent electrode and exposing the third transparent electrode in correspondence to the exposed first transparent electrode; a fourth transparent electrode disposed below the second light absorbing layer; and a second metal electrode pad disposed below the exposed third transparent electrode.

In some embodiments, the first, second, third, and fourth transparent electrodes may be formed of a transparent conductive oxide thin layer.

In other embodiments, the first transparent electrode may be formed of at least one of n-type or p-type doped InSnO, ZnO, SnO₂, NiO, Cu₂SrO₂, CuInO₂:Ca, ZnO:Ga, and InO:Mo.

In still other embodiments, the third transparent electrode may be formed of at least one of n-type or p-type doped InSnO, ZnO, SnO₂, NiO, Cu₂SrO₂, CuInO₂:Ca, ZnO:Ga, and InO:Mo.

In even other embodiments, the second and fourth transparent electrodes may be formed of at least one of n-type doped InSnO, ZnO, SnO₂, NiO, Cu₂SrO₂, CuInO₂:Ca, and ZnO:Ga.

In yet other embodiments, the first light absorbing layer may be formed of a GROUP I-III-VI2 compound semiconductor having a larger bandgap than the second light absorbing layer.

In further embodiments, the first light absorbing layer may be formed of one of CuGaSe, CuGaSeS, CuAlSe, CuAlSeS, CuGaS, and CuAlS.

In still further embodiments, the second light absorbing layer may be formed of one of CuInGaSe, CuInGaSeS, or CuInSe.

In even further embodiments, the bifacial solar cells may further include a first buffer layer between the first light absorbing layer and the second transparent electrode or a second buffer layer between the second light absorbing layer and the fourth transparent electrode.

In yet further embodiments, the bifacial solar cells may further include a first intrinsic layer between the first buffer layer and the second transparent electrode or a second intrinsic layer between the second buffer layer and the fourth transparent electrode.

In yet further embodiments, the first and second intrinsic layers may be formed of material identical or different to undoped or shallow doped material of the second or fourth transparent electrode.

In yet further embodiments, the bifacial solar cell may further include an anti-reflection layer on the second transparent electrode;

In yet further embodiments, the bifacial solar cell may further include at least one grid electrode disposed at least one side of the anti-reflection layer and contacting the second transparent electrode.

In other embodiments of the present invention, the bifacial solar cells may further include a second grid electrode on at least one edge of the fourth transparent electrode in correspondence to the first grid electrode.

In some embodiments, at least one of the first and second grid electrodes may be formed of material identical to at least one of the first and second metal electrode pads.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a sectional view illustrating a bifacial solar cell according to an embodiment of the present invention; and

FIGS. 2A through 2F are sectional views illustrating a method of manufacturing a bifacial solar cell according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the dimensions of layers and regions are exaggerated for clarity of illustration. Like reference numerals refer to like elements throughout.

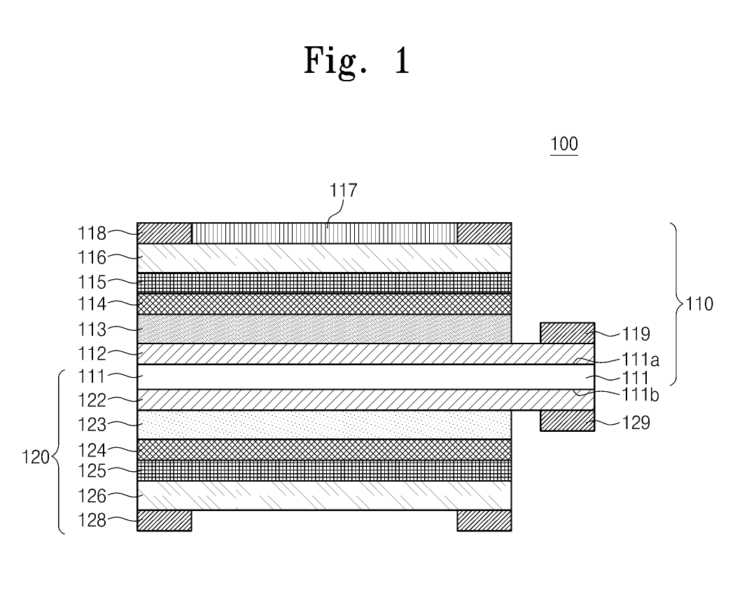

FIG. 1 is a sectional view illustrating a bifacial solar cell according to an embodiment of the present invention.

Referring to FIG. 1, the bifacial solar cell 100 has a four terminal tandem cell structure including a first transparent cell 110 and a second transparent cell 120 which is an inverse structure of the first transparent cell 110. The first transparent cell 110 and the second transparent cell 120 share a transparent substrate 111 therebetween.

The first transparent cell 100 as a front solar cell may include the transparent substrate 111 including first and second sides 111a and 111b facing each other, a first transparent electrode 112 disposed on the first side 111a of the transparent substrate 111 and having the broader width than upper layers thereon at one edge, a first light absorbing layer 113, a first buffer layer 114, a first intrinsic layer 115, a second transparent electrode 116, an anti-reflection layer 117, at least one grid electrode 118 disposed on at least one end of the side of the anti-reflection layer 117 and contacting the second transparent electrode 116, and a first metal electrode pad 119 disposed on the exposed first transparent electrode 112.

The transparent substrate 111 may be a sodalime glass (SLG) substrate. The SLG substrate 111 is known as a relatively cheap substrate material. Additionally, sodium of the SLG substrate 111 spreads into the first light absorbing layer 113 and the second absorbing layer 123 so that photovoltaic characteristic of the solar cell 100 may improved. This is because the sodium helps to form organization of a compound semiconductor thin layer well, serves as a protective layer at the grain boundary, improves p-type electrical conductivity, and reduces defects of the compound semiconductor thin layer.

The first transparent electrode 112 may be formed of a material having a high optical transmittance and excellent electrical conductivity. For example, the first transparent electrode 112 may be formed of a Transparent Conductive Oxide (TCO) thin layer. The TOC thin layer may be formed of at least one of n-type or p-type doped InSnO, ZnO, SnO₂, NiO, Cu₂SrO₂, CuInO₂:Ca, ZnO:Ga, and InO:Mo.

The first light absorbing layer 113 has a bandgap ranging from about 1.0 eV to about 1.6 eV to improve efficiency and durability, and may be formed of a GROUP I-III-VI₂ compound semiconductor. The first light absorbing layer 113 may be formed of a chalcopyrite based compound semiconductor such as CuGaSe(CGS), CuGaSeS(CGSS), CuAlSe(CAS), CuAlSeS(CASS), CuGaS, CuGaS, and CuAlS. The first light absorbing layer 113 is a p-type semiconductor.

The first buffer layer 114 may be provided for excellent bonding between the first light absorbing layer 113 and the second transparent electrode 116 since the first light absorbing layer 113 and the second transparent electrode 116 have large differences between lattice constants and between bandgaps. It is preferable that the first buffer layer 114 has a bandgap between those of the first light absorbing layer 113 and the second transparent electrode 116. For example, the first buffer layer 114 may be formed of at least one of CdS, ZnS, Zn(O,SOH)x or In(OH)S. The first buffer layer 114 is an n-type semiconductor and may be omitted.

The second transparent electrode 116 is formed on the front side of the solar cell 100 to serve as a window so that the second transparent electrode 116 may be formed of a material having a high optical transmittance and excellent electrical conductivity. For example, the second transparent electrode 116 may be formed of a TCO thin layer. The TOC thin layer may be formed of at least one of n-type doped InSnO, ZnO, SnO₂, NiO, Cu₂SrO₂, CuInO₂:Ca, and ZnO:Ga. For example, the second transparent electrode 116 formed of the ZnO may have a high optical transmittance of more than about 80%.

The first intrinsic layer 115 may be provided to increase durability of minority carrier through formation of an internal electric field between pn junction. The first intrinsic layer 115 may be formed of a material having a bandgap between the first light absorbing layer 113 and the second electrode 116. The first intrinsic layer 115 may be formed of the same or different material than the undoped or shallow doped second transparent electrode 116 according to types of the first light absorbing layer 113.

The first intrinsic layer 115 may be omitted.

The anti-reflection layer 117 may reduce reflection loss of the solar light incident to the solar cell 100. Efficiency of the solar cell 100 may be improved by the anti-reflection layer 117. For one example, the anti-reflection layer 117 may be formed of MgF₂. The anti-reflection layer 117 may be omitted.

The first grid electrodes 118 collect current at the surface of the solar cell 100 and may be formed of a single layer or an alloy layer of Au, Ag, Al, Ni, and Cu. Since solar light is not incident to portions that the first grid electrodes 118 occupy, the portions occupied by the first grid electrodes 118 may need to be minimized The first grid electrodes 118 may be omitted.

The first metal electrode pad 119 may be provided spaced apart from the first absorbing layer 113. The first metal electrode pad 119 may be formed of the same material as the first grid electrodes 118. The first metal electrode pad 119 may have the same size and form as the first grid electrodes 118 or may have different sizes and forms according to optimization.

The second transparent cell 120 as a rear side solar cell includes the transparent substrate 111 having the first and second sides 111a and 111b facing each other, a third transparent electrode 122 disposed below the second side 111b of the transparent substrate 111 and having the broader width than lower layers therebelow at one edge, a second light absorbing layer 123, a second buffer layer 124, a second intrinsic layer 125, and a fourth transparent electrode 126, at least one second grid electrode 128 disposed to correspond to the first grid electrodes 118 disposed on at least one edge of the fourth transparent electrode 126, and a second metal electrode pad 129 disposed on the exposed third transparent electrode 122.

The third transparent electrode 122 may be formed of a material having a high optical transmittance and excellent electrical conductivity. For example, the third transparent electrode 122 may be formed of a TCO thin layer. The TOC thin layer may be formed of at least one of n-type or p-type doped InSnO, ZnO, SnO₂, NiO, Cu₂SrO₂, CuInO₂:Ca, ZnO:Ga, and InO:Mo and may be formed of the same or different material than the first transparent electrode 112.

The second light absorbing layer 123 may be formed of GROUP I-III-VI₂ compound semiconductor having a bandgap relatively less than the first light absorbing layer 113 to improve efficiency and durability. The second light absorbing layer 123 may be formed of a chalcopyrite based compound semiconductor such as CuInGaSe(CIGS), CuInGaSeS(CIGSS), and CuInSe(CIS). The second light absorbing layer 123 is a p-type semiconductor.

Since the second light absorbing layer 123 is formed of a material having a bandgap less than the first light absorbing layer 113 which is exposed directly to solar light, the solar light transmitted through the first light absorbing layer 113 may be absorbed by the second light absorbing layer 123 as a secondary absorbing layer. Accordingly, a wider range of wavelengths of solar light is used for photovoltaic power systems so that efficiency of the solar cell 100 may be improved.

The second buffer layer 124 may be provided for excellent bonding between the second light absorbing layer 123 and the fourth transparent electrode 126 since the second light absorbing layer 123 and the fourth transparent electrode 126 have large differences between lattice constants and between bandgaps. It is preferable that a bandgap of the second buffer layer 134 may be disposed at the middle between those of the second light absorbing layer 123 and the fourth transparent electrode 126. For example, the second buffer layer 124 may be formed of at least one of CdS, ZnS, Zn(O,SOH)x or In(OH)S. The second buffer layer 124 is an n-type semiconductor and may be omitted.

The fourth transparent electrode 126 is formed on the rear side of the solar cell 100 and may be formed of a material having a high optical transmittance and excellent electrical conductivity. For example, the fourth transparent electrode 126 may be formed of a TCO thin layer. The TOC thin layer may be formed of at least one of n-type doped InSnO, ZnO, SnO₂, NiO, Cu₂SrO₂, CuInO₂:Ca, and ZnO:Ga.

The second intrinsic layer 125 may be provided to increase durability of minority carrier through formation of an internal electric field between pn junction. The second intrinsic layer 125 may be formed of a material having a bandgap between the second light absorbing layer 123 and the fourth electrode 126. The second intrinsic layer 125 may be formed of the same or different material than the undoped fourth transparent electrode 126 according to types of the second light absorbing layer 123.

The second intrinsic layer 125 may be omitted.

The second grid electrodes 128 may be formed of a single layer or an alloy layer of Au, Ag, Al, Ni, and Cu.

The second metal electrode pad 129 may be provided spaced apart from the second absorbing layer 123. The second metal electrode pad 129 may be formed of the same material as the second grid electrodes 128. The second metal electrode pad 129 may have the same size and form as the second grid electrodes 128 or may have different sizes and forms according to optimization.

The transparent bifacial compound semiconductor solar cell 100 is a high efficient and durable transparent thin film solar cell that resolves the limitations of a typical transparent low-efficient amorphous silicon solar cell and a short-life dye-sensitized solar cell formed of transparent and highly efficient materials. Additionally, the transparent bifacial compound semiconductor solar cell 100 resolves the limitations of a bonding boundary through a high efficient tandem cell structure where both sides of the transparent substrate 111 are used as solar cells. Especially, the transparent bifacial compound semiconductor solar cell 100 may be used for a material of a Building Integrated Photo-Voltaic (BIPV) and a transparent window of a car door. Therefore, since increasing demand of a thin film solar cell and energy savings through fuel energy usage reduction are accomplished, economic added value may be increased.

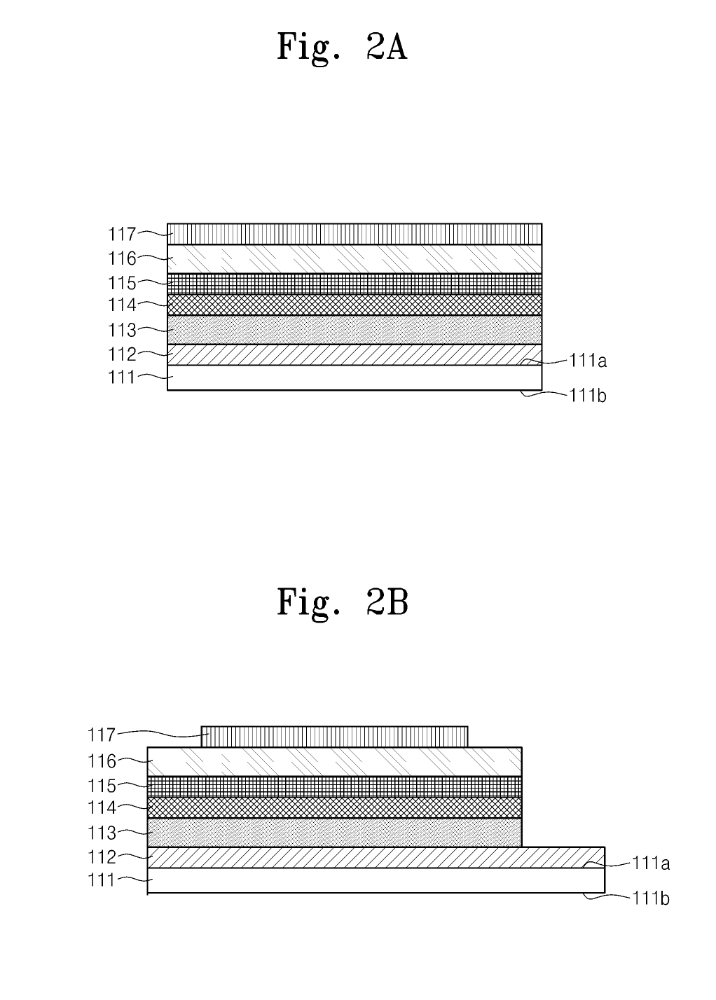

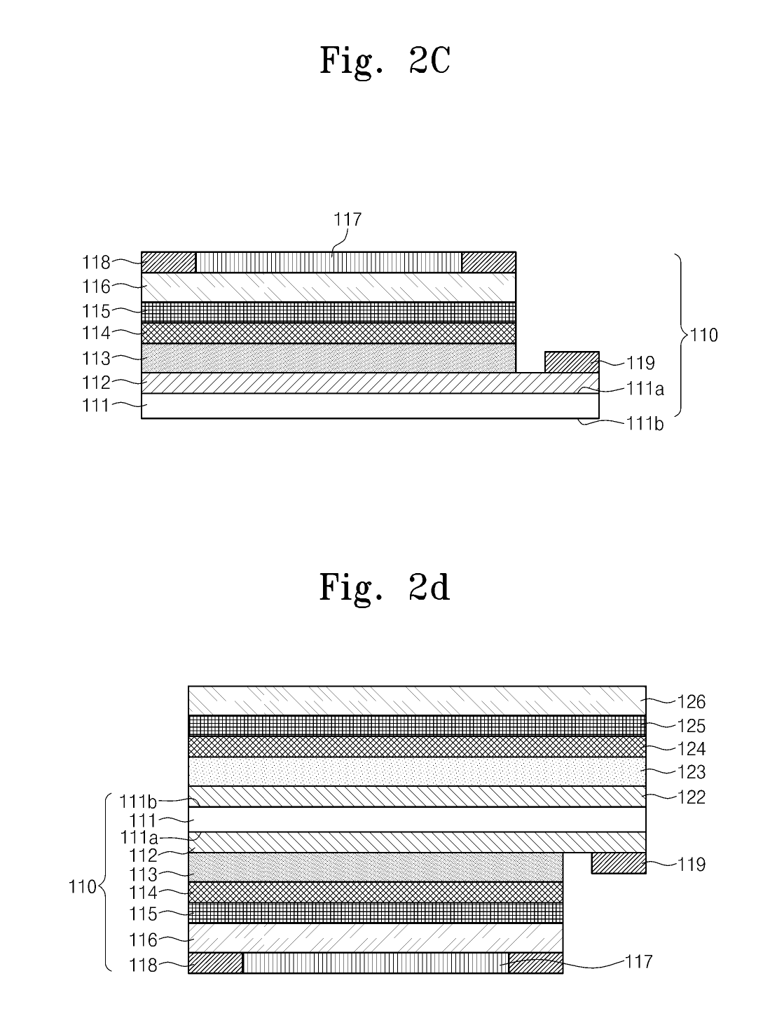

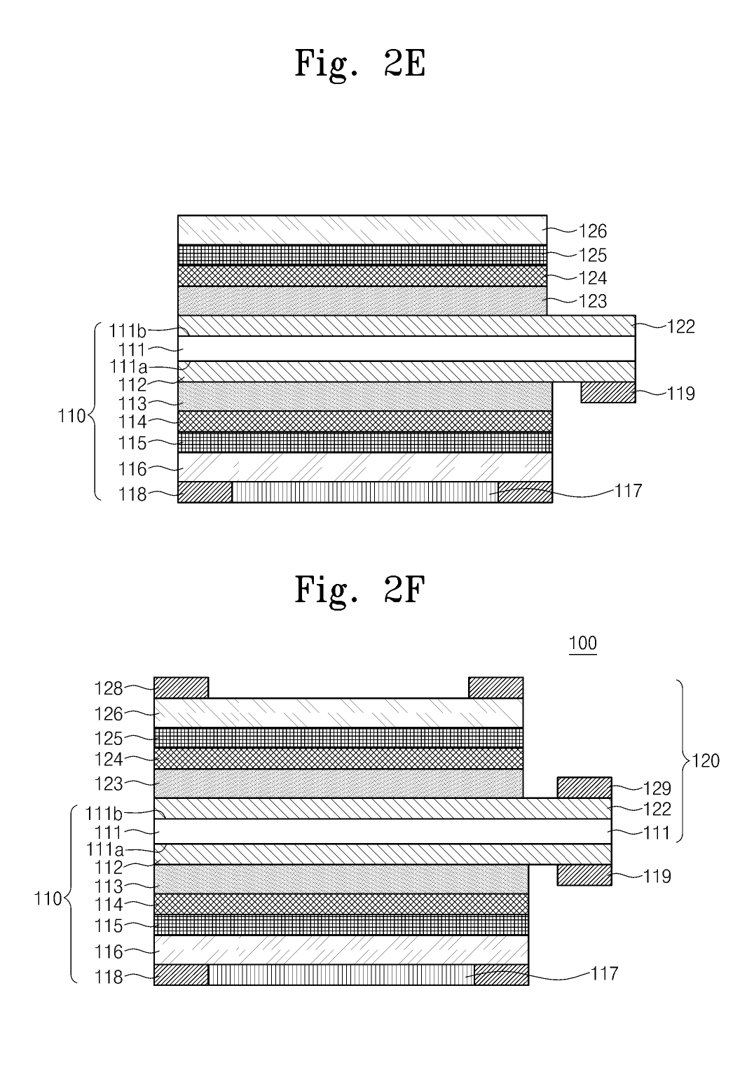

FIGS. 2A through 2F are sectional views illustrating a method of manufacturing a bifacial solar cell according to an embodiment of the present invention.

Referring to FIG. 2A, a first transparent electrode 112, a first light absorbing layer 113, a first buffer layer 114, a first intrinsic layer 115, a second transparent electrode 116, and an anti-reflection layer 117 are sequentially formed on a first side 111a of a transparent substrate 111 having first and second sides 111a and 111b facing each other.

The transparent substrate 111 may be a glass substrate or a SLG substrate.

The first transparent electrode 112 may be formed of a material having a high optical transmittance and excellent electrical conductivity. For example, the first transparent electrode 112 may be formed of a TCO thin layer. The TOC thin layer may be formed of at least one of n-type or p-type doped InSnO, ZnO, SnO₂, NiO, Cu₂SrO₂, CuInO₂:Ca, ZnO:Ga, and InO:Mo.

The first transparent electrode 112 may be formed with a sputtering method or a Pulse Laser Deposition (PLD) method. The sputtering method or the PLD method uses an appropriate deposition temperature according to a temperature condition of a subsequent process and may be performed within a range of a normal temperature (about 25° C.) to about 350° C., for example.

The first light absorbing layer 113 has a bandgap of about 1.0 eV to about 1.6 eV to improve efficiency and durability and may be formed of a GROUP I-III-VI₂ compound semiconductor having a relatively larger bandgap than the second light absorbing layer (see 123 of FIG. 2F) of the second transparent cell (see 120 of FIG. 2F) as a rear side solar cell. The first light absorbing layer 113 may be formed of a chalcopyrite based compound semiconductor such as CuGaSe(CGS), CuGaSeS(CGSS), CuAlSe(CAS), CuAlSeS(CASS), CuGaS, CuGaS, and CuAlS. The first light absorbing layer 113 is a p-type semiconductor.

The first light absorbing layer 113 may be formed through a vacuum evaporation method or non-vacuum method. As one example, the vacuum deposition method may be an evaporation method, a sputtering method, or a Chemical Vapor Deposition (CVD) method. As one example, the non-vacuum method may be a pasting method, an electroplating method, a spin coating method, or an ink printing method. Moreover, the method of forming the first light absorbing layer 113 is not limited thereto and may include various forming methods according to kinds of starting materials such as metal, binary compound, etc.

The vacuum deposition method or the non-vacuum method uses an appropriate deposition temperature according to a selected method and a temperature condition of a subsequent process and may be performed within a range of a normal temperature (about 25° C.) to about 700° C., for example.

The first buffer layer 114 may be provided for excellent bonding between the first light absorbing layer 113 and the second transparent electrode 116 since the first light absorbing layer 113 and the second transparent electrode 116 have large differences between lattice constants and between bandgaps. A bandgap of the first buffer layer 114 may be disposed between those of the first light absorbing layer 113 and the second transparent electrode 116. For example, the first buffer layer 114 may be formed of at least one of CdS, ZnS, Zn(O,SOH)x or In(OH)S. The first buffer layer 114 is an n-type semiconductor.

The first buffer layer 114 may be formed through the vacuum deposition method or a Chemical Bath Deposition (CBD) method. At this point, a deposition temperature is lower than a point at which damage and characteristic deterioration of the first absorbing layer 113 do not occur and, when a temperature of more than the above point is required, the above methods are performed within a diffusion distance by diffusion coefficients of components.

When the first buffer layer 114 is formed through a wet process like the CBD method, it is better to perform a sequent process after a cleansing process is performed to prevent pollution. Moreover, the first buffer layer 114 may be omitted.

The first intrinsic layer 115 may be provided to increase durability of minority carrier through formation of an internal electric field between pn junction. The first intrinsic layer 115 may be formed of a material having a bandgap between the first light absorbing layer 113 and the second electrode 116. The first intrinsic layer 115 may be formed of the same or different material than the undoped or shallow doped second transparent electrode 116 according to types of the first light absorbing layer 113.

The first intrinsic layer 115 may be formed with vacuum deposition through the sputtering method or the PLD method. Moreover, the first intrinsic layer 115 may be omitted.

The second transparent electrode 116 is formed on the front side of the solar cell 100 to serve as a window so that the second transparent electrode 116 may be formed of a material having a high optical transmittance and excellent electrical conductivity. For example, the second transparent electrode 116 may be formed of a TCO thin layer. The TOC thin layer may be formed of at least one of n-type doped InSnO, ZnO, SnO₂, NiO, Cu₂SrO₂, CuInO₂:Ca, and ZnO:Ga.

The second transparent electrode 116 may be formed with vacuum deposition through the sputtering method or the PLD method. The first light absorbing layer 113, the first intrinsic layer 115, and the second transparent electrode 116 form a p-i-n junction.

The anti-reflection layer 117 may reduce reflection loss of the solar light incident to the solar cell 100 of FIG. 2F. Efficiency of the solar cell 100 may be improved by the anti-reflection layer 117. For one example, the anti-reflection layer 117 may be formed of MgF₂.

The anti-reflection layer 117 may be formed with vacuum deposition through the sputtering method or the PLD method. Moreover, the anti-reflection layer 117 may be omitted.

Referring to FIG. 2B, one edge of the first transparent electrode 112 is exposed by firstly etching the first light absorbing layer 113, the first buffer layer 114, the first intrinsic layer 115, the second transparent electrode 116, and the anti-reflection layer 117.

The first etching may be performed using a typical photolithography process and this may be performed through patterning using a mask (not shown). At this point, the mask may be a photosensitive layer pattern. The photolithography process is well known to those skilled in the art and its detailed description will be omitted.

At least one edge of the remaining second transparent electrode 116 is exposed by secondly etching at least one edge of the anti-reflection layer 117. Here, a case that the edges at both sides of the remaining anti-reflection layer 117 are exposed will be described.

The second etching may be performed using a typical photolithography process and this may be performed through patterning using a mask (not shown). At this point, the mask may be a photosensitive layer pattern. The photolithography process is well known to those skilled in the art and its detailed description will be omitted.

The present invention is not limited to the performing of the second etching after the first etching. Thus, after at least one region of the second transparent electrode 116 where the first grid electrode 118 of FIG. 2C is to be formed, one edge of the first transparent electrode 112 may be exposed where the first metal electrode pad 119 of FIG. 2C is to be formed.

Referring to FIG. 2C, at least one first grid electrode 118 is formed on the exposed second transparent electrode 116 and the first metal electrode pad 119 is formed on the exposed first transparent electrode 112.

The first grid electrodes 118 and the first metal electrode pad 119 may be formed of a single layer or an alloy layer of Au, Ag, Al, Ni, and Cu.

Since solar light is not incident to a region that the first grid electrodes 118 occupy, the region may be formed with the minimum size. The first metal electrode pad 119 is formed spaced apart from the first absorbing layer 113, and size and form of the first metal electrode 119 may have same or different than that of the first grid electrodes 118.

The first grid electrodes 118 and the first metal electrode pad 119 may be formed through the vacuum deposition method or the non-vacuum deposition method. The vacuum deposition method may be an evaporation method. The non-vacuum deposition method may be a screen printing method.

The first grid electrodes 118 and the first metal electrode pad 119 may be formed by forming a metal thin layer on an entire area of the remaining anti-reflection layer 117 and the exposed first transparent electrode 112, and then performing a typical photolithography process thereon. The photolithography process may be performed through pattering using a mask (not shown). At this point, the mask may be a photosensitive layer pattern. The photolithography process is well known to those skilled in the art and thus its detailed description will be omitted. Thereby, the first transparent cell 110 as a front side solar cell is completed.

Referring to FIG. 2D, a third transparent electrode 122, a second light absorbing layer 123, a second buffer layer 124, a second intrinsic layer 125, and a fourth transparent 126 are sequentially formed on the second side 111b of the transparent substrate 111.

The third transparent electrode 122 may be formed of a material having a high optical transmittance and excellent electrical conductivity. For example, the third transparent electrode 122 may be formed of a TCO thin layer. The TOC thin layer may be formed of at least one of n-type or p-type doped InSnO, ZnO, SnO₂, NiO, Cu₂SrO₂, CuInO₂:Ca, ZnO:Ga, and InO:Mo and may be formed of the same or different material than the first transparent electrode 112.

The third transparent electrode 122 may be formed with vacuum deposition through a sputtering method or a PLD method. The sputtering method or the PLD method may be performed at a temperature equal to the deposition temperature of the first transparent electrode 112 or lower than the deposition temperature of the first transparent electrode 112 within a range of a normal temperature (about 25° C.) to about 350° C.

The second light absorbing layer 123 may be formed of GROUP I-III-VI₂ compound semiconductor having a relatively less bandgap than the first light absorbing layer 113 to improve efficiency of the solar cell 100 of FIG. 2F by absorbing the solar light transmitted through the first light absorbing layer 113. For example, the second light absorbing layer 123 may be formed of a chalcopyrite based compound semiconductor such as CuInGaSe(CIGS), CuInGaSeS(CIGSS), and CuInSe(CIS).

The second light absorbing layer 123 may be formed using the vacuum deposition method or the non-vacuum method at a lower temperature then the deposition temperature of the first light absorbing layer 113 within a range of a normal temperature (about 25° C.) to about 700° C.

The second buffer layer 124 may be formed through the vacuum deposition method or the CBD method. At this point, the deposition temperature is lower than a point at which damage and characteristic deterioration of the first absorbing layer 113 do not occur and, when a temperature of more than the above point is required, the above methods are performed within a diffusion distance by diffusion coefficients of components.

Except for the formation materials and the deposition temperatures of the third transparent electrode 122 and the second light absorbing layer 123 and the deposition temperature of the second buffer layer 124, formation materials and methods of the remaining components may be the same as those of the first transparent electrode 112, the first light absorbing layer 113, the first buffer layer, and the first intrinsic layer 115, and the second transparent electrode 116. Therefore, their descriptions will be omitted. Moreover, the second buffer layer 124 and the second intrinsic layer 125 may be omitted.

Referring to FIG. 2E, one edge of the third transparent electrode 122 corresponding to the first transparent electrode 112 may be exposed by etching the second light absorbing layer 123, the second buffer layer 124, the second intrinsic layer 125, and the fourth transparent electrode 126.

The etching may be performed using a typical photolithography process and this may be performed through patterning using a mask (not shown). At this point, the mask may be a photosensitive layer pattern. The photolithography process is well known to those skilled in the art and its detailed description will be omitted.

Referring to FIG. 2F, at least one second grid electrode 128 corresponding to the first grid electrode 118 are formed at at least one edge on the remaining fourth transparent electrode 126, and a second metal electrode pad 129 is formed on the exposed second transparent electrode 122.

The second grid electrodes 128 and the second metal electrode pad 129 may be formed of a single layer or an alloy layer of Au, Ag, Al, Ni, and Cu. The second metal electrode pad 129 is formed spaced apart from the second absorbing layer 123, and size and form of the second metal electrode pad 129 may have same or different than that of the second grid electrodes 128.

The second grid electrodes 128 and the second metal electrode pad 129 may be formed through the vacuum deposition method or the non-vacuum deposition method. The vacuum deposition method may be an evaporation method. The non-vacuum deposition method may be a screen printing method.

The second grid electrodes 128 and the second metal electrode pad 129 may be formed by forming a metal thin layer on the second transparent electrode 126 and the exposed third transparent electrode 122 and then performing a typical photolithography process thereon. The photolithography process may be performed through pattering using a mask (not shown). At this point, the mask may be a photosensitive layer pattern. The photolithography process is well known to those skilled in the art and thus its detailed description will be omitted.

Thereby, the second transparent cell 120 as the rear side solar cell is completed. As a result, the bifacial solar cell 100 including the first and second transparent cells 110 and 120 and having a tandem structure where the first and second transparent cells 110 and 120 share the transparent substrate 111 is completed.

The bifacial solar cell 100 uses the both sides of the transparent substrate 111 as solar cells, thereby forming a tandem structure of a high efficient solar cell structure and resolving the limitations of a bonding boundary. Additionally, the second light absorbing layer 123 (where a process temperature is high due to a relatively high bandgap) is formed before the first light absorbing layer 113, so that deterioration characteristics occurring during manufacturing processes may be prevented.

In an embodiment of the present invention, it is described that after the forming of the first transparent cell 110, the second transparent cell 120 is formed. However, the present invention is not limited thereto. Only if a condition that the first light absorbing layer 113 is formed before the second light absorbing layer 123 is satisfied, it is apparent that the remaining other processes may be performed in parallel in consideration of an manufacturing order during the forming of the first transparent cell 110 and the second transparent cell 120.

According to an embodiment of the present invention, a bifacial solar cell with high efficiency and improved durability is provided, and thus may be used for a material of a Building Integrated Photo-Voltaic (BIPV) and a transparent window of a car door. Therefore, since places demanding a thin film solar cell expand and energy savings through fuel energy usage reduction are accomplished, economic added value may be increased.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A bifacial solar cell comprising:
a transparent substrate having a first side and a second side facing each other;
a first transparent electrode disposed on the first side of the transparent substrate;
a first light absorbing layer disposed on the first transparent electrode and exposing the first transparent electrode at one edge;
a second transparent electrode disposed on the first light absorbing layer;
a first metal electrode pad disposed on the exposed first transparent electrode;
a third transparent electrode disposed below the second side of the transparent substrate;
a second light absorbing layer disposed below the third transparent electrode and exposing the third transparent electrode in correspondence to the exposed first transparent electrode;
a fourth transparent electrode disposed below the second light absorbing layer; and
a second metal electrode pad disposed below the exposed third transparent electrode.

2. The bifacial solar cell of claim 1, wherein the first, second, third, and fourth transparent electrodes are formed of a transparent conductive oxide thin layer.

3. The bifacial solar cell of claim 2, wherein the first transparent electrode is formed of at least one of n-type or p-type doped InSnO, ZnO, SnO₂, NiO, Cu₂SrO₂, CuInO₂:Ca, ZnO:Ga, and InO:Mo.

4. The bifacial solar cell of claim 3, wherein the third transparent electrode is formed of at least one of n-type or p-type doped InSnO, ZnO, SnO₂, NiO, Cu₂SrO₂, CuInO₂:Ca, ZnO:Ga, and InO:Mo.

5. The bifacial solar cell of claim 2, wherein the second and fourth transparent electrodes are formed of at least one of n-type doped InSnO, ZnO, SnO₂, NiO, Cu₂SrO₂, CuInO₂:Ca, and ZnO:Ga.

6. The bifacial solar cell of claim 1, wherein the first light absorbing layer is formed of a GROUP I-III-VI₂ compound semiconductor having a larger bandgap than the second light absorbing layer.

7. The bifacial solar cell of claim 6, wherein the first light absorbing layer is formed of one of CuGaSe, CuGaSeS, CuAlSe, CuAlSeS, CuGaS, and CuAlS.

8. The bifacial solar cell of claim 6, wherein the second light absorbing layer is formed of one of CuInGaSe, CuInGaSeS, or CuInSe.

9. The bifacial solar cell of claim 5, further comprising a first buffer layer between the first light absorbing layer and the second transparent electrode or a second buffer layer between the second light absorbing layer and the fourth transparent electrode.

10. The bifacial solar cell of claim 9, further comprising a first intrinsic layer between the first buffer layer and the second transparent electrode or a second intrinsic layer between the second buffer layer and the fourth transparent electrode.

11. The bifacial solar cell of claim 10, wherein the first and second intrinsic layers are formed of material identical or different to undoped or shallow doped material of the second or fourth transparent electrode.

12. The bifacial solar cell of claim 1, further comprising an anti-reflection layer on the second transparent electrode.

13. The bifacial solar cell of claim 12, further comprising at least one grid electrode disposed at least one side of the anti-reflection layer and contacting the second transparent electrode.

14. The bifacial solar cell of claim 13, further comprising a second grid electrode on at least one edge of the fourth transparent electrode in correspondence to the first grid electrode.

15. The bifacial solar cell of claim 14, wherein at least one of the first and second grid electrodes is formed of material identical to at least one of the first and second metal electrode pads.
